(19) United States
(12) Patent Application Publication
(10) Pub. No.: US 2020/0277313 A1
(43) Pub. Date: Sep. 3, 2020

(54) PEROVSKITE, METHOD FOR PRODUCING SAME, AND SOLAR BATTERY COMPRISING SAME

(71) Applicants: Global Frontier Center for Multiscale Energy, Seoul (KR); Seoul National University R&DB Foundation, Seoul (KR)

(72) Inventors: Man Soo Choi, Seoul (KR); Namyoung Ahn, Seoul (KR); Kwisung Kwak, Gyeonggi-do (KR)

(21) Appl. No.: 15/778,051

(22) PCT Filed: Jul. 18, 2016
(86) PCT No.: PCT/KR2016/007791

§ 371 Date: May 22, 2018

(30) Foreign Application Priority Data
Nov. 24, 2015 (KR) 10-2015-0164744

(51) Int. Cl. C07F 7/24; H01L 31/0224

(52) U.S. Cl. CPC C07F 7/24; H01L 31/022425

(57) ABSTRACT

The present invention provides a perovskite containing two or more anions and two or more cations being mixed. The perovskite is represented by Formula 1:

[AₐB_{b}C_{c}]Pb[X_{d}YₑW_{f}] (1)
wherein A, B, and C are each independently an organic or inorganic cation; X, Y, and W are each independently F⁻, Cl⁻, Br⁻ or I⁻ as a halogen ion; a, b, and c satisfy the relations of a+b+c=1, 0.05≤a≤0.95, 0≤b≤0.95, and 0≤c≤0.95; and d, e, and f satisfy the relations of d+e+f=3, 0.05≤d≤3, 0≤e≤2.95, and 0≤f≤2.95, provided that when both b and c are 0, e and f are not simultaneously 0, and vice versa. The perovskite of the present invention has improved structural stability and electrochemical properties compared to existing perovskites containing a single cation and a single anion. The present invention also provides an electronic device including the perovskite.

### BACKGROUND OF THE INVENTION

### 1. Field of the Invention

The present invention relates to a perovskite, and more specifically to a perovskite which contains two or more anions and two or more cations being mixed to achieve improved structural stability. The present invention also relates to a method for preparing the perovskite.

### 2. Description of the Related Art

Conventional perovskite (CH₃NH₃PbI₃) materials used in light-absorbing layers of perovskite solar cells are formed into thin films by solution spin-coating processes, achieving high efficiency (≥15%). Thin perovskite absorber layers formed by simple spin-coating processes known in the art have low homogeneity and quality, making it difficult to fabricate solar cells with ultra-high efficiency (≥19%). The fabrication of solar cells with ultra-high efficiency (≥19%) requires methods for producing perovskite light-absorbing layers with high density and excellent crystallinity by improving homogeneity and quality of the layers.

Since the report on the 9.7% solid-state perovskite solar cells employing MAPbI₃ (MA=CH₃NH₃) and spiro-MeOTAD, overcoming the dissolution problem of MAPbI₃ in liquid electrolyte, there is a rapid growth in perovskite solar cell researches due to easy fabrication procedure and superb photovoltaic performance in both mesoscopic structure and planar structure. As a result, power conversion efficiency (PCE) of 201.1% was certified by the U.S. National Renewable Energy Laboratory (NREL).

MAPbI₃ layer for perovskite solar cells can be prepared using either one-step coating or sequential two-step coating method. It was reported that photovoltaic performance of devices prepared by two-step coating method was superior to one-step coating method.

### SUMMARY OF THE INVENTION

The present invention is intended to propose a perovskite having a novel structure that can be used to form a perovskite film whose stability is better than that of existing perovskite thin films, a method for preparing the perovskite, and an ultra-high-efficiency perovskite solar cell using the perovskite.

One aspect of the present invention provides a perovskite represented by Formula 1:

[AₐB_{b}C_{c}]Pb[X_{d}YₑW_{f}] (1)

wherein A, B, and C, which may be identical to or different from each other, are each independently an organic or inorganic cation; X, Y, and W, which may be identical to or different from each other, are each independently F⁻, Cl⁻, Br⁻ or I⁻ as a halogen ion; a, b, and c satisfy the relations of a+b+c=1, 0.05≤a≤0.95, 0≤b≤0.95, and 0≤c≤0.95; and d, e, and f satisfy the relations of d+e+f=3, 0.05≤d≤3, 0≤e≤2.95, and 0≤f≤2.95, provided that when both b and c are 0, e and f are not simultaneously 0, and vice versa.

A further aspect of the present invention provides an adduct compound represented by Formula 5:

[(AZ₁)ₚ(BZ₂)_{q}(CZ₃)ᵣ].Pb(Z₄)₂.Q (5)

wherein A, B, and C, which may be identical to or different from each other, are each independently an organic or inorganic cation; Z₁, Z₂, Z₃, and Z₄, which may be identical to or different from each other, are each independently F⁻, Cl⁻, Br⁻ or I⁻ as a halogen ion; Q is a Lewis base including a functional group containing an atom with an unshared pair of electrons as an electron pair donor; and p, q, and r satisfy the relations of p+q+r=1, 0.05≤p≤0.95, 0.05≤q≤0.95, and 0≤r≤0.90.

Another aspect of the present invention provides a method for preparing the perovskite.

Yet another aspect of the present invention provides a solar cell or electronic device comprising the perovskite.

The perovskite of the present invention has a novel structure in which two or more cations and two or more anions are mixedly present, achieving improved structural stability. Due to this stable structure, the perovskite of the present invention can be used to fabricate solar cells with improved stability and low hysteresis. In addition, the perovskite of the present invention can be utilized in perovskite photodetectors and electronic devices such as LEDs as well as perovskite solar cells.

### BRIEF DESCRIPTION OF THE DRAWINGS

FIG. 1 shows XRD spectra of perovskite films produced in Example 1 and Comparative Example 1.

FIG. 2 shows UV-Vis absorption spectra of perovskite films produced in Example 1 and Comparative Example 1.

FIG. 3 shows changes in the stability of perovskite films produced in (a) Example 1 and (b) Comparative Example 1 as a function of time in the dark.

FIG. 4 shows changes in the stability of perovskite films produced in (a) Example 1 and (b) Comparative Example 1 as a function of time under illumination.

FIG. 5 shows images of perovskite films produced in Example 1 and Comparative Example 1 after storage for 6 hours under illumination and in the dark.

FIG. 6 shows (a) current density-voltage (J-V) curves of perovskite solar cells fabricated in Example 2 and Comparative Example 2 and (b) time-dependent changes in the power conversion efficiency of the solar cells to characterize the stability of the solar cells.

FIG. 7 is a J-V curve showing the hysteresis of a perovskite solar cell fabricated in Example 2.

FIG. 8 shows changes in (a) V_{oc}, (b) J_{sc}, (c) fill factor, and (d) power conversion efficiency (PCE, %) of a perovskite solar cell fabricated in Example 2 as a function of time.

FIG. 9 shows a cross-sectional SEM images of a solar cell including a perovskite and a C60 electron transport layer, which was fabricated in Example 2.

FIG. 10 shows J_{sc} and PCE (%) values of a solar cell including a perovskite and a C60 electron transport layer, which was fabricated in Example 2.

### DETAILED DESCRIPTION OF THE INVENTION

The present invention will now be described in more detail.

The present invention provides a perovskite represented by Formula 1:

[AₐB_{b}C_{c}]Pb[X_{d}YₑW_{f}] (1)

wherein A, B, and C, which may be identical to or different from each other, are each independently an organic or inorganic cation; X, Y, and W, which may be identical to or different from each other, are each independently F⁻, Cl⁻, Br⁻ or I⁻ as a halogen ion; a, b, and c satisfy the relations of a+b+c=1, 0.05≤a≤0.95, 0≤b≤0.95, and 0≤c≤0.95; and d, e, and f satisfy the relations of d+e+f=3, 0.05≤d≤3, 0≤e≤2.95, and 0≤f≤2.95, provided that when both b and c are 0, e and f are not simultaneously 0, and vice versa.

According to one embodiment, both c and f may be 0. In this embodiment, a and b may satisfy the relations of a+b=1, 0.2≤a≤0.9 or 0.3≤a≤0.8, and 0.1≤b≤0.8 or 0.2≤b≤0.7, d and e may satisfy the relations of d+e=3, 2≤d≤3 or 2.5≤d≤2.95, and 0≤e≤1 or 0.05≤e≤0.5.

More preferably, when both c and f are 0, a and b satisfy 0.35≤a≤0.65 and 0.35≤b≤0.65, and d and e satisfy 2.8≤d≤3 and 0≤e≤0.2.

According to one embodiment, A, B, and C in Formula 1 may be each independently an organic cation represented by Formula 2:

(R₁R₂N═CH—NR₃R₄)⁺ (2)

wherein R₁, R₂, R₃, and R₄ are each independently selected from hydrogen and substituted or unsubstituted C₁-C₆ alkyl,

an organic cation represented by Formula 3:

(R₅R₆R₇R₈N)⁺ (3)

wherein R₅, R₆, R₇, and R₈ are each independently hydrogen, substituted or unsubstituted C₁-C₂₀ alkyl or substituted or unsubstituted aryl, or

a Cs⁺ cation.

More specifically, A, B, and C in Formula 1 may be each independently selected from CH₃NH₃⁺ (methylammonium, MA), CH(NH₂)₂⁺ (formamidinium, FA), and Cs⁺.

The perovskite of the present invention contains two or more organic or inorganic cations, in particular, those selected from the cations of Formulae 2 and 3, which are mixed. The cations of Formulae 2 and 3 may be present in a molar ratio of about 2:8 to about 5:5, preferably about 3:7 to about 5:5, and most preferably about 3:7 to about 4:6.

According to one embodiment, the perovskite of Formula 1 may be a compound represented by Formula 4:

[CH₃NH₃]ₐ[CH(NH₂)₂]_{b}Pb[Br]_{d}[I]ₑ (4)

wherein a, b, c, and d are as defined in Formula 1.

More preferably, a and b in Formula 4 satisfy the relations of a+b=1, 0.05≤a≤0.95, and 0.05≤b≤0.95, and d and e satisfy the relations of d+e=3, 0.05≤d≤2.95, and 0.05≤e≤2.95.

The skeleton of the perovskite can be modified by varying the individual anions in the mixed anions. According to the present invention, the anions allow the perovskite to have a cubic structure. That is, the presence of the anions facilitates control over the characteristics of the perovskite and leads to an improvement in the performance of a photoelectronic device including the perovskite.

The alteration of the organic cation (or organic cations) present in the perovskite can usually affect the structural and/or physical properties of the perovskite. The electronic properties and optical properties of the material can be controlled by changing the organic cations used, which is particularly useful in controlling the characteristics of a photoelectronic device including the perovskite. For example, the conductivity of the material may be increased or decreased by changing the organic cations. Further, when the organic cations vary, the band structure of the material may be modified, for example, so that the bandgap of the semiconductor material can be controlled.

According to one embodiment, the composition of the cations and the halogen anions being mixed in the perovskite may be changed such that the perovskite has a cubic crystal structure at room temperature.

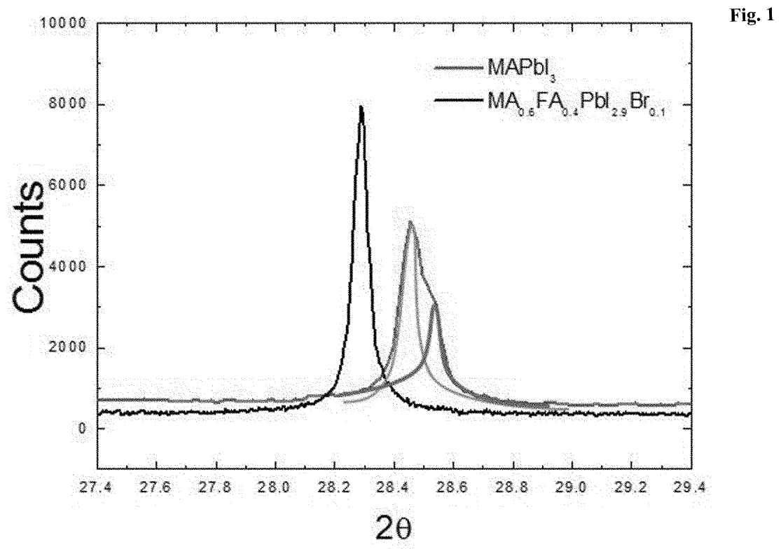

Referring to the XRD pattern shown in FIG. 1, MAPbI₃ as a typical perovskite material has a tetragonal structure. In contrast, the perovskite of the present invention in which the composition of the cations and the anions is variable has a cubic structure that shows a single peak corresponding to the (200) plane at 20 angles between 27° and 29°.

A perovskite crystal should meet the geometric condition given by Equation 1:

$$t = \frac{( {r}_{c} + {r}_{a} )}{\sqrt{2} ( {r}_{P b} + {r}_{a} )} \qquad ( 1 )$$

where r_{c} is the average ionic radius of a cation, rₐ is the average ionic radius of an anion, r_{Pb} is the ionic radius of Pb²⁺ cation, and t is the tolerance factor that is associated with the stability and shape (such as distortion) of the crystal structure.

As the tolerance factor t approaches 1, the perovskite has a structure close to cubic. Particularly, the tolerance factor is frequently used to describe the perovskite structure and can also be used to calculate the interchangeability of ions in the crystal structure. For the perovskite structure, the t value may be from 0.7 to 1, preferably from 0.7 to 0.9, and more preferably from 0.8 to 0.9.

According to one embodiment, the tolerance factor may be calculated from the average ionic radii of the cations and the halogen ions present in the perovskite according to the present invention.

The perovskite of the present invention may form a more stable phase due to its cubic structure with a t value in the range defined above. For example, the perovskite of the present invention can maintain its more stable phase under illumination conditions, ensuring very high stability against exposure to light. Meanwhile, in the case where a perovskite has a non-cubic crystal structure (for example, a tetragonal structure), the crystal structure may become unstable when exposed to light although the t value of the perovskite is in the range defined above. For example, the perovskite may undergo a phase transition, losing its structural stability. The difference in stability between a cubic perovskite structure and a tetragonal perovskite structure may increase over time.

The absorbance of the perovskite according to the present invention at a wavelength of 500 nm after being exposed to AM1.5 illumination for 6 hours is 80% or more, preferably 90% or more, of its initial value.

The absorbance of the perovskite according to the present invention at a wavelength of 500 nm when being exposed to AM 1.5 illumination for 12 hours is 50% or more of its initial value. This high absorbance retention indicates markedly improved stability of the perovskite according to the present invention under illumination conditions.

The present invention also provides an adduct compound as a precursor for the preparation of the perovskite, represented by Formula 5:

[(AZ₁)ₚ(BZ₂)q(CZ₃)ᵣ].Pb(Z₄)₂.Q (5)

wherein A, B, and C are each independently an organic or inorganic cation; Z₁, Z₂, Z₃, and Z₄ are each independently F⁻, Cl⁻, Br⁻ or I⁻ as a halogen ion; Q is a Lewis base including a functional group containing an atom with an unshared pair of electrons as an electron pair donor; and p, q, and r satisfy the relations of p+q+r=1, 0.05≤p≤0.95, 0.05≤q≤0.95, and 0≤r≤0.90.

The atom with an unshared pair of electrons is a nitrogen (N), oxygen (O) or sulfur (S) atom and the FT-IR peak of the functional group in the compound of Formula 5 is red-shifted by 1 to 10 cm⁻¹ relative to that in a compound represented by Formula 6:

Pb(Z₄)₂.Q (6)

wherein Z₄ and Q are as defined in Formula 5.

The present invention also provides a method for preparing the adduct compound.

The present invention also provides a perovskite prepared by using the adduct compound.

Q in Formula 5 is a Lewis base including a functional group containing a nitrogen (N), oxygen (O) or sulfur (S) atom as an electron pair donor. Specifically, Q in Formula 5 may be a Lewis base including at least one functional group selected from the group consisting of H₂O, thioamide, thiocyanate, thioether, thioketone, thiol, thiophene, thiourea, thiosulfate, thioacetamide, carbonyl, aldehyde, carboxyl, ether, ester, sulfonyl, sulfo, sulfinyl, thiocyanato, pyrrolidone, peroxy, amide, amine, imide, imine, azide, pyridine, pyrrole, nitro, nitroso, cyano, nitroxy, and isocyano groups, each of which has a nitrogen, oxygen or sulfur atom as an electron pair donor. A compound including at least one functional group selected from the group consisting of thioamide, thiocyanate, thioether, thioketone, thiol, thiophene, thiourea, thioacetamide, and thiosulfate groups, each of which has a sulfur (S) atom as an electron pair donor, is more preferred because of its ability to form a strong bond with the lead halide.

More specifically, Q in Formula 5 may be one or more selected from the group consisting of H₂O, dimethyl sulfoxide (DMSO), N,N-dimethylacetamide (DMA), N-methyl-2-pyrrolidione (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine, and n-propylamine. Preferably, Q in Formula 5 is selected from thiourea (TU), N,N-dimethylthioacetamide (DMTA), and thioacetamide (TAM), each of which includes a sulfur (S) atom as an electron pair donor.

According to the present invention, the FT-IR peak corresponding to the functional group containing the electron pair donor atom where the Lewis base represented by Q is bonded to Pb is red-shifted by 10 to 30 cm⁻¹ relative to that in the compound of Formula 6. This red shift is explained by the formation of the adduct from the bonding of the Pb metal atom to the Lewis base. That is, this adduct formation weakens the bonding strength of the functional group containing the electron pair donor of the Lewis base. This leads to strong bonding of the Lewis base to Pb, affecting the bonding strength of the electron pair donating functional group. This result is because the lead halide acts as a Lewis acid to form the adduct via Lewis acid-base reaction with the Lewis base. Specifically, the lead halide and the Lewis base share the unpaired electron in the Lewis base to form a bond, which further stabilizes the phase of the lead halide adduct.

The Lewis base may be in the form of a liquid and is preferably non-volatile or only slightly volatile. The Lewis base may have a boiling point of 120° C. or above, for example 150° C. or above.

The present invention also provides a method for preparing the lead halide adduct represented by Formula 5, including: dissolving a lead halide, two or more organic or inorganic halides, and a Lewis base including a nitrogen (N), oxygen (O) or sulfur (S) atom as an electron pair donor in a first solvent to prepare a precursor solution; and adding a second solvent to the precursor solution and collecting the resulting precipitate by filtration.

The lead halide, the halides including a cation, and the organic material including a ligand may be mixed in a molar ratio of 1:1:1-1.5, most preferably 1:1:1.

According to one embodiment, the first solvent may be an organic solvent that can dissolve the lead halide, the organic or inorganic halides, and the organic material including a functional group containing a nitrogen (N), oxygen (O) or sulfur (S) atom as an electron pair donor, and may be selected from the group consisting of propanediol-1,2-carbonate (PDC), ethylene carbonate (EC), diethylene glycol, propylene carbonate (PC), hexamethylphosphoric triamide (HMPA), ethyl acetate, nitrobenzene, formamide, γ-butyrolactone (GBL), benzyl alcohol, N-methyl-2-pyrrolidone (NMP), acetophenone, ethylene glycol, trifluorophosphate, benzonitrile (BN), valeronitrile (VN), acetonitrile (AN), 3-methoxypropionitrile (MPN), dimethyl sulfoxide (DMSO), dimethyl sulfate, aniline, N-methylformamide (NMF), phenol, 1,2-dichlorobenzene, tri-n-butyl phosphate, o-dichlorobenzene, selenium oxychloride, ethylene sulfate, benzenethiol, dimethylacetamide, diethylacetamide, N,N-dimethylethanamide (DMEA), 3-methoxypropionitrile (MPN), diglyme, cyclohexanol, bromobenzene, cyclohexanone, anisole, diethylformamide (DEF), dimethylformamide (DMF), 1-hexanethiol, hydrogen peroxide, bromoform, ethyl chloroacetate, 1-dodecanethiol, di-n-butyl ether, dibutyl ether, acetic anhydride, m-xylene, p-xylene, chlorobenzene, morpholine, diisopropyl ethylamine, diethyl carbonate (DEC), 1-pentanediol, n-butyl acetate, and 1-hexadecanethiol. The first solvent can be used alone or in the form of the mixture of two or more.

The first solvent may be added in an excessive amount. Preferably, the first solvent is added in such an amount that the weight ratio of the lead halide to the first solvent is 1:1-3.

According to one embodiment, the second solvent may be a nonpolar or weakly polar solvent that is capable of selectively removing the first solvent. For example, the second solvent may be selected from the group consisting of acetone-based solvents, C₁-C₃ alcohol-based solvents, ethyl acetate-based solvents, diethyl ether-based solvents, alkylene chloride-based solvents, cyclic ether-based solvents, and mixtures thereof.

According to one embodiment, the use of toluene and chlorobenzene as general volatile solvents for the preparation of the perovskite from the lead halide adduct may lead to low reproducibility because the quality of the perovskite is significantly dependent on dripping amount and/or spinning rate of washing solution and the difference in solubility between the solvent for washing and the solvent in the precursor solution. In contrast, high reproducibility of the perovskite film can be obtained by using the second solvent, preferably a diethyl ether-based solvent, regardless of spin coating condition if enough amount of the second solvent is used for dissolving the first solvent completely.

The combined use of the first and second solvents for the preparation of the lead halide adduct allows the product to have a denser structure because the use of the volatile second solvent enables removal of the first solvent, ensuring rapid and uniform crystallization.

According to one embodiment, the lead halide adduct may form a transparent thin film. The lead halide adduct in the form of a thin film may be heated to a temperature of 30° C. or above, preferably 40° C. or above, or 50° C. or above. For example, the lead halide adduct may be heated to the temperature range of 30° C. to 150° C. to form the desired perovskite. The heating may be performed at a temperature of 30° C. to 80° C. and subsequently at a temperature of 90° C. to 150° C. The additional heating allows the perovskite crystal to have a dense structure. The annealing process enables the removal of the organic ligand corresponding to Q in Formula 5 from the crystal structure of the lead halide adduct, leading to the formation of the perovskite. According to one embodiment, the resulting perovskite thin film may have a dark color, such as dark brown.

The perovskite of the present invention is highly stable under illumination conditions. Due to this advantage, the perovskite thin film absorbs an increased amount of light and permits electrons and holes to rapidly migrate therethrough. Therefore, the use of the perovskite thin film enables the fabrication of a high-efficiency solar cell.

The present invention also provides a solar cell including a first electrode including a transparent conductive substrate, an electron transport layer formed on the first electrode, a perovskite formed on the electron transport layer, a hole transport layer formed on the perovskite layer, and a second electrode formed on the hole transport layer.

According to one embodiment, the lead halide adduct is formed into a thin film on the first electrode including a transparent substrate by a spin-coating process. The transparent substrate may be made of a transparent conductive oxide. As the transparent conductive oxide, there may be used, for example, fluorine doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (IZO-Ag-IZO), indium zinc tin oxide-silver-indium zinc tin oxide (IZTO-Ag-IZTO), aluminum zinc oxide-silver-aluminum zinc oxide (AZO-Ag-AZO), aluminum oxide (Al₂O₃), zinc oxide (ZnO) or magnesium oxide (MgO). Preferably, fluorine doped tin oxide (FTO) or indium tin oxide (ITO) is used.

The electron transport layer formed on the transparent electrode (first electrode) may include a porous metal oxide. The porous metal oxide for the porous layer may be the same as that for a blocking layer, which will be described below. Alternatively, the porous layer may include at least one metal oxide selected from TiO₂, ZnO, SrTiO₃, and WO₃ or mixtures thereof. Alternatively, the electron transport layer may be formed using a fullerene or derivatives thereof. For example, the electron transport layer may include one or more materials selected from the group consisting of C60, C70, C76, C78, C84, C90 fullerenes, and derivatives thereof. When the electron transport layer is formed using the fullerene or derivatives thereof, the transparent electrode is preferably made of ITO.

The solar cell of the present invention may further include a blocking layer between the electron transport layer and the first electrode. The blocking layer is a hole blocking layer (HBL) with a deep HOMO level that blocks the migration of holes to prevent holes from recombining with electrons. The blocking layer may include at least one metal oxide selected from TiO₂, ZnO, SrTiO₃, and WO₃ or mixtures thereof. Preferably, the blocking layer includes TiO₂. When the electron transport layer is formed using a fullerene or a fullerene derivative, the blocking layer may include bathocuproine (BCP), 4,4′,4″-tris[3-methylphenyl-N-phenylamino]triphenylamine (m-MTDATA) or polyethylene dioxythiophene (PEDOT), but preferably includes none of them.

Any suitable material known in the art may be used without limitation to form the hole transport layer. For example, the hole transport layer may include a hole transport monomer or polymer. The hole transport monomer may be 2,2′,7,7′-tetrakis(N,N-di-p-methoxyphenylamine)-9,9′-spirobifluorene (spiro-MeOTAD) and the hole transport polymer may be poly(3-hexylthiophene) (P₃HT). The hole transport layer may include a doping material. The doping material may be selected from the group consisting of, but not limited to, Li-based dopants, Co-based dopants, and combinations thereof. For example, the hole transport layer may be formed using a mixture of spiro-MeOTAD, 4-tert-butylpyridine (tBP), and Li-TFSI.

The second electrode may be made of at least one metal selected from the group consisting of Pt, Au, Ni, Cu, Ag, In, Ru, Pd, Rh, Ir, Os, C, and combinations thereof.

The lead halide adduct and the method for preparing the lead halide adduct according to the present invention can be utilized in perovskite photodetectors and LEDs as well as perovskite solar cells.

The perovskite solar cells of the present invention may have power conversion efficiency (PCE) of 17% or more, preferably 18% or more.

The method for preparing the lead halide adduct and the solar cells including the perovskite prepared by the method will be more specifically explained with reference to the following examples, including experimental examples. However, these examples are merely illustrative and should not be construed as limiting the scope of the invention.

### Example 1: Production of Perovskite (MA_{0.6}FA_{0.4}PbI_{2.9}Br_{0.1}) Thin Film

A solution of 461 mg of PbI₂, 79.5 mg of CH₃NH₃I (MAI), 11.2 mg of CH₃NH₃Br (MABr), 68.8 mg of CH(NH₂)₂I (FAI), and 78 mg of DMSO in 500 mg of DMF was spin-coated on a FTO thin film and diethyl ether (DE) was slowly dripped on the rotating substrate to obtain a transparent CH₃NH_{3(0.6)}CH(NH_{2)2(0.4)}I_{0.9}Br_{0.1}.PbI₂.DMSO adduct film. The adduct film was heated to obtain a perovskite film. The composition of the perovskite film was MA_{0.6}FA_{0.4}PbI_{2.9}Br_{0.1}.

### Comparative Example 1: Production of Perovskite (MAPbI₃) Thin Film

A solution of 461 mg of PbI₂, 159 mg of CH₃NH₃I (MAI), and 78 mg of DMSO (molar ratio 1:1:1) in 500 mg of DMF was spin-coated on a FTO thin film and diethyl ether (DE) was slowly dripped on the rotating substrate to obtain a transparent CH₃NH₃I.PbI₂.DMSO adduct film. The adduct film was heated to obtain a perovskite (MAPbI₃) film.

### Experimental Example 1: XRD Analysis of the Perovskite Films

XRD spectra of the perovskite films produced in Example 1 and Comparative Example 1 were measured. The results are shown in FIG. 1.

### Experimental Example 2: Evaluation of Stability of the Perovskites

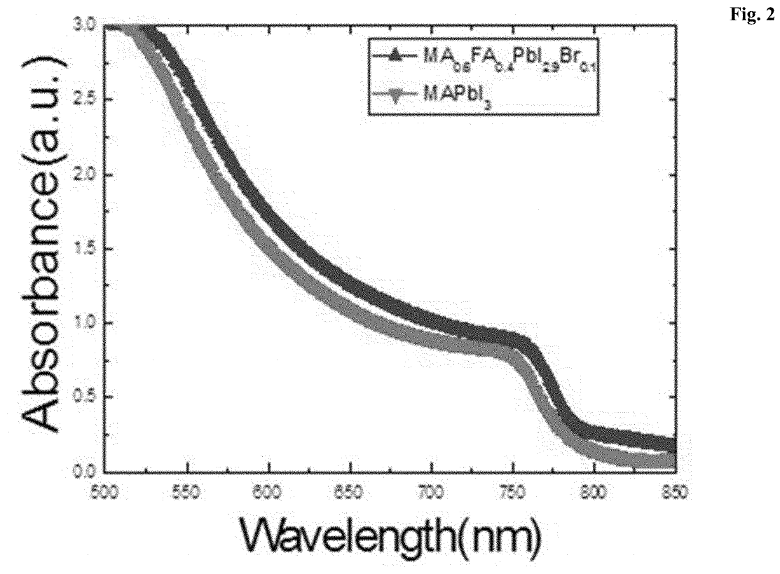

The initial absorbance values of the perovskite films produced in Example 1 and Comparative Example 1 were measured at ambient conditions (relative humidity >50%) without encapsulation and using desiccator. The results are shown in FIG. 2.

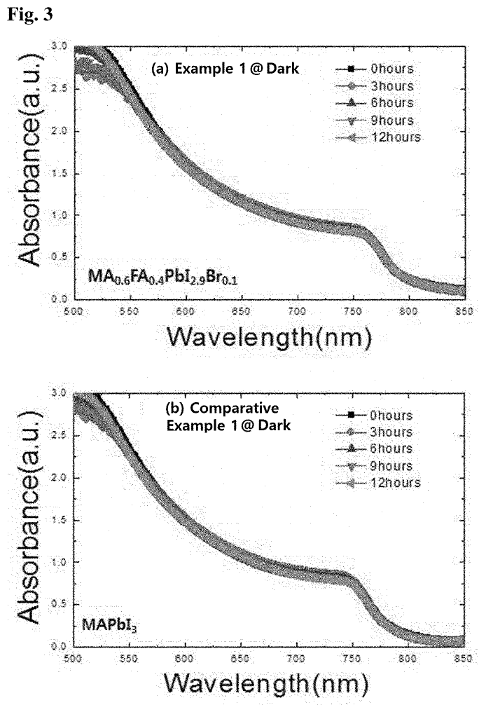

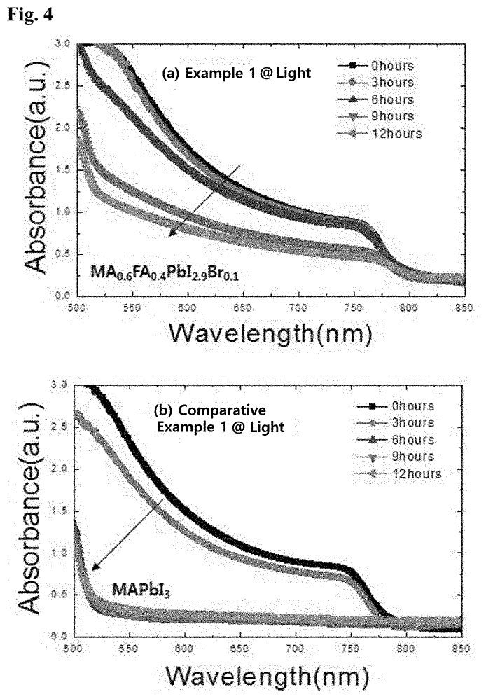

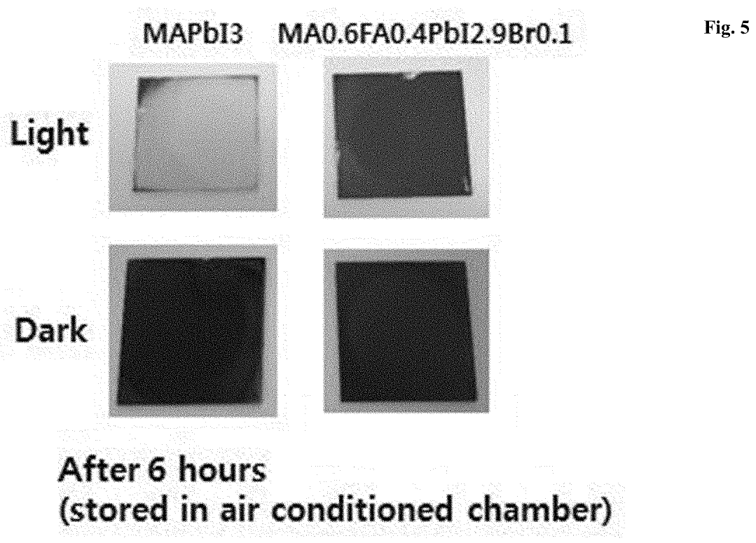

Time-dependent changes in the absorbance of the perovskite films were measured in the same atmosphere as that used for the initial absorbance measurement under the supplementary conditions, i.e., under the dark and AM 1.5G one-sun illumination (100 mW/cm²) conditions. The obtained results are shown in FIGS. 3 and 4. The states of the perovskite films were observed after storage for 6 h under each of the conditions. The obtained results are shown in FIG. 5.

From the results, it can be seen that there were slight differences in initial absorbance and time-dependent absorbance changes under the dark condition between the films of Example 1 and Comparative Example 1 but clear differences were observed in time-dependent absorbance changes under the illumination condition between the films of Example 1 and Comparative Example 1, indicating that the perovskite film of Example 1 was highly stable against illumination compared to the perovskite containing a single cation and a single anion. The high stability of the perovskite of Example 1 is explained by the cubic structure of the perovskite of Example 1 that is stable against structural changes (such as phase transformation) under illumination.

### Example 2: Fabrication of Perovskite (MA_{0.6}FA_{0.4}PbI_{2.9}Br_{0.1}) Solar Cell-C60

An ITO glass substrate (AMG, 9.5 Ωcm⁻², 25×25 mm²) was rinsed with isopropanol, acetone, and deionized water (each for 20 min) in an ultrasonic bath and stored in an oven at 120° C. before use. UVO was treated for 30 min prior to use. C60 was deposited by using thermal evaporator at a constant evaporation rate to form a C60 electron transport layer having a final thickness of 35 nm.

461 mg of PbI₂, 79.5 mg of CH₃NH₃I (MAI), 11.2 mg of CH₃NH₃Br (MABr), 68.8 mg of CH(NH₂)₂I (FAI), and 78 mg of DMSO were mixed in 500 mg of DMF at room temperature with stirring for 1 hr in order to prepare a CH₃NH_{3(0.6)}CH(NH₂)_{2(0.4)}I_{0.9}Br_{0.1}.PbI₂.DMSO adduct solution. The completely dissolved solution was spin-coated on the C60 layer at 4000 rpm for 25 sec and 0.5 ml of diethyl ether (DE) was slowly dripped on the rotating substrate in 10 sec before the surface of the layer changed to be turbid caused by evaporization of DMF. The obtained transparent CH₃NH_{3(0.6)}CH(NH₂)_{2(0.4)}I_{0.9}Br_{0.1}.PbI₂.DMSO adduct film was heated at 65° C. for 1 min and further heated at 100° C. for 2 min in order to obtain a dark-brown MA_{0.6}FA_{0.4}PbI_{2.9}Br_{0.1} film having a dense structure.

20 μl of a spiro-MeOTAD solution was spin-coated on the perovskite layer at 3000 rpm for 3 sec. The spiro-MeOTAD solution was composed of 72.3 mg spiro-MeOTAD (Merck), 28.8 μl of 4-tert-butylpyridine, and 17.5 μl of a lithium bis(trifluoromethanesulfonyl)imide (Li-TFSI) solution (520 mg Li-TSFI in 1 ml acetonitrile (Sigma-Aldrich, 99.8%)) in 1 ml of chlorobenzene. Finally, Au electrode was deposited by using thermal evaporator at a constant evaporation rate.

### Comparative Example 2: Fabrication of Perovskite (MAPbI₃) Solar Cell

A perovskite solar cell was fabricated in the same manner as in Example 2, except that a perovskite film was formed as follows.

461 mg of PbI₂, 159 mg of MAI, and 78 mg of DMSO (molar ratio 1:1:1) were mixed in 600 mg of DMF at room temperature with stirring for 1 hr in order to prepare a MAI.PbI₂.DMSO adduct solution. The completely dissolved solution was spin-coated on the C60 layer at 4000 rpm for 25 sec and 0.5 ml of diethyl ether (DE) was slowly dripped on the rotating substrate in 10 sec before the surface of the layer changed to be turbid caused by evaporization of DMF. The obtained transparent MAI.PbI₂.DMSO adduct film was heated at 65° C. for 1 min and further heated at 100° C. for 2 min in order to obtain a dark-brown MAI.PbI₂ film having a dense structure.

### Experimental Example 3: Evaluation of Electrochemical Properties of the Solar Cells

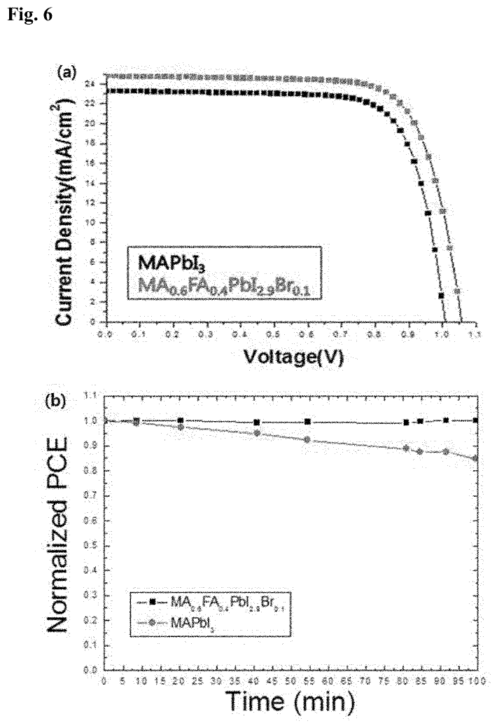

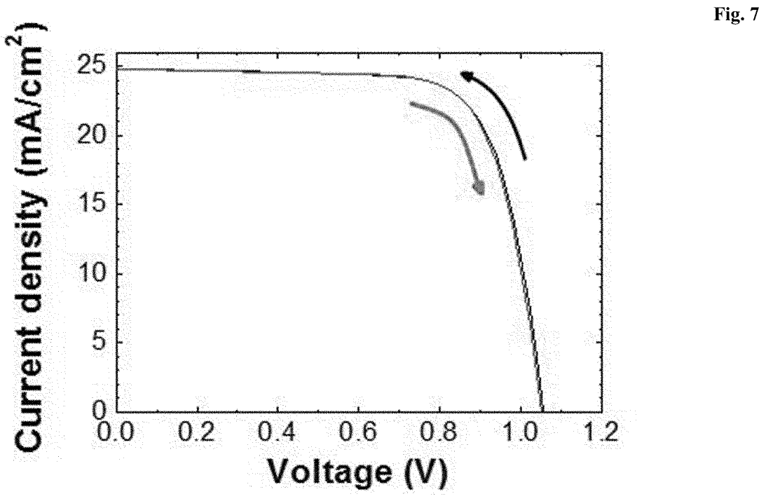

FIG. 6 shows (a) current density-voltage curves of the solar cells fabricated in Example 2 and Comparative Example 2 and (b) time-dependent changes in the power conversion efficiency of the solar cells to characterize the stability of the solar cells. The short-circuit current (J_{sc}), open-circuit voltage (V_{oc}), fill factor (FF), and power conversion efficiency (PCE) values of the solar cells fabricated in Example 2 and Comparative Example 2 are described in Table 1 below. The scan direction test of the solar cell of Example 2 was performed to evaluate for the J-V hysteresis of the solar cell. The results are shown in FIG. 7.

TABLE 1

| Device # | J_{sc} (mA/cm²) | V_{oc} (V) | FF | PCE (%) |
|---|---|---|---|---|
| Example 2 | 24.81 | 1.05 | 73.85 | 19.35 |
| Comparative | 23.29 | 1.00 | 74.66 | 17.52 |
| Example 2 | | | | |

As can be seen from the results in Table 1, the solar cell of Example 2 showed better results in terms of current density and open-circuit voltage than the solar cell of Comparative Example 2. In addition, the power conversion efficiency of the solar cell of Example 2 was ≥1% higher than that of the solar cell of Comparative Example 2.

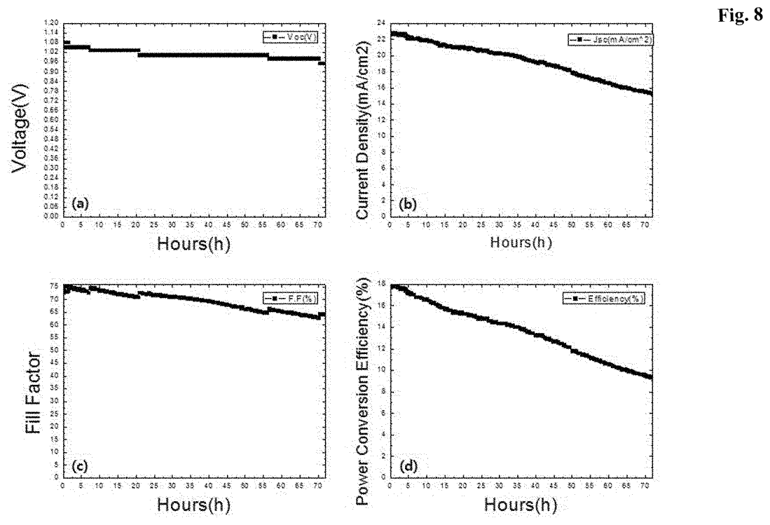

FIG. 8 shows the retentions of (a) open-circuit voltage (V_{oc}), (b) short-circuit current (J_{sc}), (c) fill factor (FF), and (d) power conversion efficiency (PCE, %) of the solar cell fabricated in Example 2, as a function of time. Based on these paraments, the electrochemical stability of the solar cell can be determined. An important requirement for photoelectronic devices may be stability during their anticipated lifetime. Due to the presence of cations and anions being mixed, the perovskite prepared in Example 1 is very structurally stable and can be used to fabricate a photoelectronic device or an electronic device with high stability, power conversion efficiency, and photocurrent.

The current density, open-circuit voltage, and FF of the solar cell fabricated in Example 2 after 70 h were maintained at ≥80% of their initial values, demonstrating high electrochemical stability of the solar cell. The power conversion efficiency of the solar cell fabricated in Example 2 after 70 h was maintained at at least ˜50% of its initial value.

### Experimental Example 4: Evaluation of Electrochemical Properties of a Solar Cell Including the C60 Electron Transport Layer

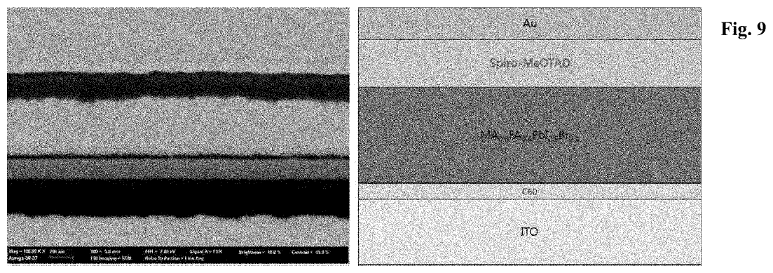

FIG. 9 shows a cross-sectional structure of the solar cell including the C60 electron transport layer (Example 2) and a SEM image of the structure. As shown in the SEM image, the constituent layers of the solar cell were very uniformly stacked with well-defined boundaries therebetween.

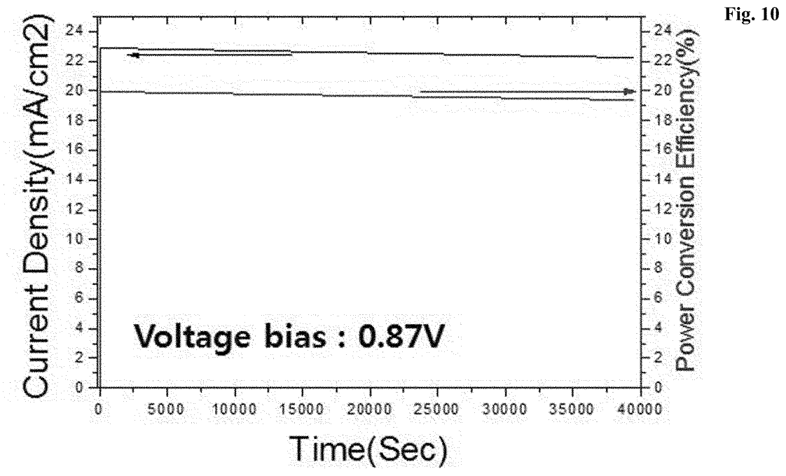

FIG. 10 shows the retentions of the current density and power conversion efficiency of the solar cell fabricated in Example 2 as a function of time. The results in FIG. 10 show that the initial power conversion efficiency of the solar cell was as high as at least about 19% and was maintained at least approximately 90% even after 40,000 sec (i.e. ˜10 hrs), indicating excellent life characteristics of the solar cell.

These results conclude that the use of the perovskite according to the present invention can provide a solar cell with excellent electrochemical properties as well as high stability against illumination. In addition, the perovskite of the present invention can exhibit excellent performance in solar cells including a C60 electron transport layer.

The perovskite of the present invention forms a more stable phase, achieving improved structural stability under illumination conditions. Thus, the solar cell of the present invention has excellent electrochemical properties and markedly improved life stability. In addition, the lead halide adduct compound and the preparation method thereof according to the present invention can be utilized in perovskite photodetectors and LEDs as well as perovskite solar cells.

While specific embodiments of the invention have been described in detail, it will be appreciated by those skilled in the art that such detailed descriptions are merely preferred embodiments and the scope of the present invention is not limited thereto.

Therefore, the true scope of the present invention should be defined by the appended claims and their equivalents.

1. A perovskite represented by Formula 1:
[AₐB_{b}C_{c}]Pb[X_{d}YₑW_{f}] (1)
wherein A, B, and C are identical to or different from each other and are each independently an organic or inorganic cation; X, Y, and W are identical to or different from each other and are each independently F⁻, Cl⁻, Br⁻ or I⁻ as a halogen ion; a, b, and c satisfy the relations of a+b+c=1, 0.05≤a≤0.95, 0≤b≤0.95, and 0≤c≤0.95; and d, e, and f satisfy the relations of d+e+f=3, 0.05≤d≤3, 0≤e≤2.95, and 0≤f≤2.95, provided that when both b and c are 0, e and f are not simultaneously 0, and vice versa.

2. The perovskite according to claim 1, wherein when both c and f in Formula 1 are 0, a and b satisfy the relations of a+b=1, 0.2≤a≤0.9, and 0.1≤b≤0.8, and d and e satisfy the relations of d+e=3, 2≤d≤2.95, and 0.05≤e≤1.

3. The perovskite according to claim 1, wherein when both c and f are 0, a and b satisfy 0.35≤a≤0.65 and 0.35≤b≤0.65, and d and e satisfy 2.8≤d≤3 and 0≤e≤0.2.

4. The perovskite according to claim 1, wherein the perovskite comprises a cubic structure at room temperature.

5. The perovskite according to claim 1, wherein the perovskite has a single x-ray diffraction (XRD) peak corresponding to the (200) plane at 20 angles between 27° and 29°.

6. The perovskite according to claim 1, wherein the perovskite meets the geometric condition given by Equation 1:
$$t = \frac{( {r}_{c} + {r}_{a} )}{\sqrt{2} ( {r}_{P b} + {r}_{a} )} \qquad ( 1 )$$
where r_{c} is the average ionic radius of the cations, rₐ is the average ionic radius of the anions, and r_{Pb} is the ionic radius of Pb²⁺ cation, and
the t value calculated by Equation 1 is from 0.7 to 1.

7. The perovskite according to claim 6, wherein the t value is 0.8 or above.

8. The perovskite according to claim 1, wherein A, B, and C in Formula 1 are each independently an organic cation represented by Formula 2:
(R₁R₂N═CH—NR₃R₄)⁺ (2)
wherein R₁, R₂, R₃, and R₄ are each independently selected from hydrogen and substituted or unsubstituted C₁-C₆ alkyl,
an organic cation represented by Formula 3:
(R₅R₆R₇R₈N)⁺ (3)
wherein R₅, R₆, R₇, and R₈ are each independently hydrogen, substituted or unsubstituted C₁-C₂₀ alkyl or substituted or unsubstituted aryl, or
a Cs⁺ cation.

9. The perovskite according to claim 8, wherein A, B, and C in Formula 1 are each independently selected from the organic cations of Formulae 2 and 3 and the organic cations of Formulae 2 and 3 are present in a molar ratio of 2:8 to 5:5.

10. The perovskite according to claim 1, wherein A, B, and C in Formula 1 are each independently selected from CH₃NH₃⁺, CH(NH₂)₂⁺, and Cs⁺.

11. The perovskite according to claim 1, wherein the perovskite of Formula 1 is a compound represented by Formula 4:
[CH₃NH₃]ₐ[CH(NH₂)₂]_{b}Pb[Br]_{d}[I]ₑ (4)
wherein a and b satisfy the relations of a+b=1, 0.05≤a≤0.95, and 0.05≤b≤0.95, and d and e satisfy the relations of d+e=3, 0.05≤d≤2.95, and 0.05≤e≤2.95.

12. The perovskite according to claim 1, wherein the absorbance of the perovskite at a wavelength of 500 nm after being exposed to AM 1.5 one-sun illumination (100 mW/cm²) for 6 hours is 80% or more of its initial value.

13. The perovskite according to claim 1, wherein the absorbance of the perovskite at a wavelength of 500 nm after being exposed to AM 1.5 one-sun illumination (100 mW/cm²) for 12 hours is 50% or more of its initial value.

14. An adduct compound represented by Formula 5:
[(AZ₁)ₚ(BZ₂)_{q}(CZ₃)ᵣ]Pb(Z₄)₂.Q (5)
wherein A, B, and C are identical to or different from each other and are each independently an organic or inorganic cation; Z₁, Z₂, Z₃, and Z₄ are identical to or different from each other and are each independently F⁻, Cl⁻, Br⁻ or I⁻ as a halogen ion; Q is a Lewis base comprising a functional group containing an atom with an unshared pair of electrons as an electron pair donor; and p, q, and r satisfy the relations of p+q+r=1, 0.05≤p≤0.95, 0.05≤q≤0.95, and 0≤r≤0.90.

15. The adduct compound according to claim 14, wherein Q in Formula 5 is one or more selected from the group consisting of H₂O, dimethyl sulfoxide (DMSO), N,N-dimethylacetamide (DMA), N-methyl-2-pyrrolidione (MPLD), N-methyl-2-pyridine (MPD), 2,6-dimethyl-γ-pyrone (DMP), acetamide, urea, thiourea (TU), N,N-dimethylthioacetamide (DMTA), thioacetamide (TAM), ethylenediamine (EN), tetramethylethylenediamine (TMEN), 2,2′-bipyridine (BIPY), 1,10-piperidine, aniline, pyrrolidine, diethylamine, N-methylpyrrolidine, and n-propylamine.

16. The adduct compound according to claim 14, wherein Q in Formula 5 is a Lewis base comprising at least one functional group selected from the group consisting of thioamide, thiocyanate, thioether, thioketone, thiol, thiophene, thiourea, thiosulfate, thioacetamide, carbonyl, aldehyde, carboxyl, ether, ester, sulfonyl, sulfo, sulfinyl, thiocyanato, pyrrolidone, peroxy, amide, amine, imide, imine, azide, pyridine, pyrrole, nitro, nitroso, cyano, nitroxy, and isocyano groups.

17. A method for preparing a perovskite, comprising:
dissolving a lead halide, two or more organic or inorganic halides, and a Lewis base comprising a nitrogen (N), oxygen (O) or sulfur (S) atom as an electron pair donor in a first solvent to prepare a precursor solution;
adding a second solvent to the precursor solution and filtering the resulting precipitate to obtain the adduct compound according to claim 14; and
heating the adduct compound.

18. The method according to claim 17, wherein the adduct compound is heated to a temperature of 30° C. or above to remove the Lewis base therefrom.

19. The method according to claim 17, wherein the first solvent is dimethylformamide (DMF) and the second solvent is diethyl ether.

20. A solar cell, comprising:
a first electrode comprising a transparent conductive substrate;
an electron transport layer formed on the first electrode;
the perovskite according to claim 1 formed on the electron transport layer;
a hole transport layer formed on the perovskite layer; and
a second electrode formed on the hole transport layer.

21. The solar cell according to claim 20, wherein the electron transport layer is formed by using a fullerene or a fullerene derivative.

22. The solar cell according to claim 20, wherein the electron transport layer comprises C60 or C70 and is formed in direct contact with the first electrode.

23. The solar cell according to claim 20, wherein the solar cell has an initial power conversion efficiency (PCE) of 18% or more.

24. An electronic device comprising the perovskite according to claim 1.

25. The electronic device according to claim 24, which is a photoelectronic device.
